(19) United States
(12) Patent Application Publication
(10) Pub. No.: US 2026/0123478 A1
(43) Pub. Date: Apr. 30, 2026

(54) INTEGRATED CIRCUIT PACKAGE AND MANUFACTURING METHOD

(71) Applicant: STMICROELECTRONICS INTERNATIONAL N.V., Geneva (CH)

(72) Inventor: Younes BOUTALEB, Grenoble (FR)

(21) Appl. No.: 19/321,477

(22) Filed: Sep. 8, 2025

(30) Foreign Application Priority Data
Sep. 19, 2024 (FR) 2409984

(51) Int. Cl. H01L 23/498; H01L 21/48; H01L 23/00; H01L 23/31

(52) U.S. Cl. CPC H10W 70/635; H10W 70/095; H10W 74/124; H10W 72/884; H10W 90/724; H10W 90/754

(57) ABSTRACT

The present disclosure provides for packaging integrated circuits. In an example package, an adhesive is contained between a rear face of a chip and a front face of a carrier substrate when the chip is placed and attached on the carrier substrate. In this regard, the rear face of the chip has first blind holes and the front face of the carrier substrate has second blind holes defining housings used to contain the adhesive.

### CROSS REFERENCE TO RELATED APPLICATION(S)

This application claims the priority benefit of French patent application number FR2409984, filed on Sep. 19, 2024, entitled “BOITIER DE CIRCUIT INTEGRE ET PROCEDE DE FABRICATION”, which is hereby incorporated by reference to the maximum extent allowable by law.

### TECHNICAL FIELD

Embodiments and implementations relate to the field of packaging integrated circuits, and more specifically the structure and manufacturing of integrated circuit packages, for example but not exclusively optical packages.

### BACKGROUND

Packages conventionally comprise a support substrate on which at least one electronic chip is mounted.

This chip typically has contact pads on its front face which are electrically connected to bond fingers (known to a person skilled in the art) arranged on the front face of the support substrate by electrically conductive bond wires (this operation is known to a person skilled in the art as wire bonding).

However, during the operation to mount the chip on the support substrate, the former is bonded by means of an adhesive layer.

But when the chip is pressed onto the adhesive layer, the latter may in some cases overhang part of at least some of the bond fingers of the carrier substrate and/or rise up along the side walls of the chip to at least partially cover at least some of the contact pads of the chip.

This results in contamination of these parts covered by the adhesive which leads to a defect in the wire bonding and therefore a malfunction in the integrated circuit.

There is therefore a need to remedy this drawback.

### BRIEF SUMMARY

According to one embodiment, it is proposed to contain the adhesive between the rear face of the chip and the front face of the carrier substrate when the chip is placed and attached on the carrier substrate.

According to one aspect, a package is proposed comprising an electronic chip including a front face having contact pads and a rear face having a plurality of first blind holes spread around its periphery and opening onto the rear face.

Although it is not essential, it is recommended to provide at least four first blind holes.

A chip is generally rectangular (possibly with equal sides thus forming a square).

In this case, the four first blind holes are preferably arranged in the vicinity of the four corners of the rear face of the electronic chip.

The package also has a carrier substrate having a front face (or mounting face) opposite and at a distance from the rear face of the electronic chip.

The front face of the carrier substrate has bond fingers and a plurality of second blind holes opening onto the front face respectively opposite the first blind holes of the chip.

When the rear face of the electronic chip has at least four first blind holes, the front face of the carrier substrate has at least four second blind holes.

The rear face of the chip can have four other first blind holes respectively arranged between the four first blind holes and in this case, the front face of the carrier substrate has four other second blind holes respectively located opposite the other four first blind holes.

Each pair of a first blind hole and a second blind hole facing each other defines a housing.

The package then has a pillar of a first adhesive material, for example a pillar of solidified adhesive, in each housing.

The package also has electrically conductive bond wires between the contact pads of the chip and the bond fingers of the substrate.

The package also has an encapsulating material, for example a molding resin, covering the bond wires and at least partially the electronic chip.

One part of this encapsulating material is located in the space between the rear face of the chip and the front face of the carrier substrate.

Thus, according to this aspect, the electronic chip is attached to the substrate by means of adhesive material pillars.

And this adhesive material is contained in each housing formed by a pair of a first blind hole and a second blind hole.

There is therefore no contamination of the contact pads and bond fingers which enables the bond wires to be properly bonded to these contact pads, on the one hand, and to the bond fingers, on the other.

In some packages, the encapsulating material completely covers the electronic chip.

However, this is not the case for an optical package, i.e. a package designed to contain a chip fitted with an optical device for emitting and/or receiving optical signals.

Indeed, for such a package, the encapsulating material only partially covers the electronic chip.

More specifically and according to one embodiment, the optical package has an optically transparent element, for example glass, located opposite and at a distance from the front face of the chip and attached to this front face by a bead of a second adhesive material, for example an adhesive bead.

This second adhesive material may be identical to or different from the first adhesive material.

This bead of the second adhesive material defines with the chip and the optically transparent element a cavity which is not filled by the encapsulating material.

Generally speaking, a person skilled in the art will be able to define the geometric characteristics of the first blind holes and second blind holes as well as the quantity of first adhesive material so as to obtain adhesive pillars filling these blind holes whilst providing a space between the rear face of the chip and the front face of the carrier substrate.

That being said, the second blind holes can be 25 micrometers deep to within 10%.

In practice, the carrier substrate can be a laminate substrate.

Such a substrate has alternating metallic and electrically insulating layers.

Metal tracks formed in the metallic layers and vias between these tracks provide an interconnection network between the bond fingers on the front face (upper face) of the carrier substrate and solder balls arranged on the rear face (lower face) of the carrier substrate and intended to be soldered to a printed circuit board.

The upper face of the upper electrically insulating layer of the carrier substrate forming the front face of this carrier substrate and the second blind holes can be formed in the upper electrically insulating layer and have a depth corresponding to the thickness of this upper insulating layer.

The second blind holes can have, by way of example, an opening of 200 micrometers to within 10%.

The first blind holes (formed on the rear face of the chip) may have a depth less than that of the second blind holes, for example a depth of 10 micrometers to within 10%.

According to one embodiment, each pillar of the first adhesive material overhangs the front face of the carrier substrate by 20 micrometers to within 10%.

The space between the rear face of the electronic chip and the front face of the substrate therefore has this value of 20 micrometers to within 10%.

According to another aspect, a method for manufacturing a package is proposed.

This method comprises providing an electronic chip including a front face having contact pads and a rear face,
forming on the rear face a plurality of first blind holes spread around the periphery of this rear face and opening onto this rear face.

The method also comprises providing a carrier substrate having a front face having an area intended to be opposite the rear face of the chip and the bond fingers outside of this area.

This area is a placement area above which the chip is intended to be located.

The method then comprises forming at the periphery of the area a plurality of second blind holes opening onto the front face.

The method subsequently comprises filling the second blind holes with a first adhesive material in the liquid state in an amount so as to obtain a surplus of first material overhanging the second blind holes.

This surplus remains localized in the volume located above each second blind hole due to the edge effect and its surface tension.

The next step, typically just after the filling, is placing the rear face of the chip opposite and at a distance from the area so as to align the first blind holes and the second blind holes respectively and allow penetration of the surplus of first material into the first blind holes.

The method then comprises solidifying the first material, typically by curing at an appropriate temperature, so as to obtain pillars of the first material extending into each pair of a first blind hole and a second blind hole and into the space between this first and this second blind hole.

The next step is bonding bond wires between the contact pads and the bond fingers.

The method then comprises covering the bond wires and at least part of the electronic chip with an encapsulating material which is also inserted into the space between the rear face of the chip and the front face of the carrier substrate.

According to one embodiment, at least four first blind holes are formed and at least four second blind holes are formed.

According to one embodiment suitable for a rectangular chip, the four first blind holes are formed in the vicinity of the four corners of the rear face of the chip.

To increase the attachment of the chip to the carrier substrate, four other first blind holes are formed on the rear face of the chip and respectively arranged between the four first blind holes and four other second blind holes are formed on the front face of the carrier substrate and respectively intended to be located opposite the other four first blind holes when the electronic chip is placed.

The electronic chip can be completely covered with the encapsulating material.

Alternatively and according to one embodiment, prior to the covering, an optically transparent element, for example glass, is attached opposite and at a distance from the front face of the chip by a bead of a second adhesive material defining with the chip and the optically transparent element a cavity which is not filled by the encapsulating material during covering.

### BRIEF DESCRIPTION OF THE DRAWINGS

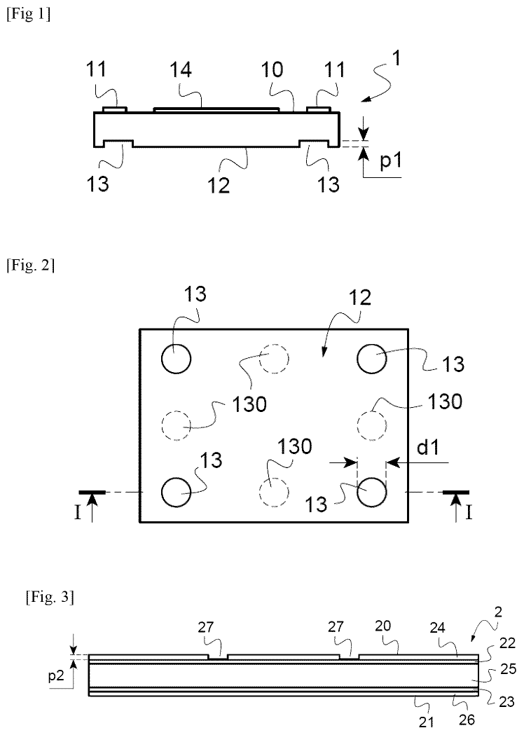

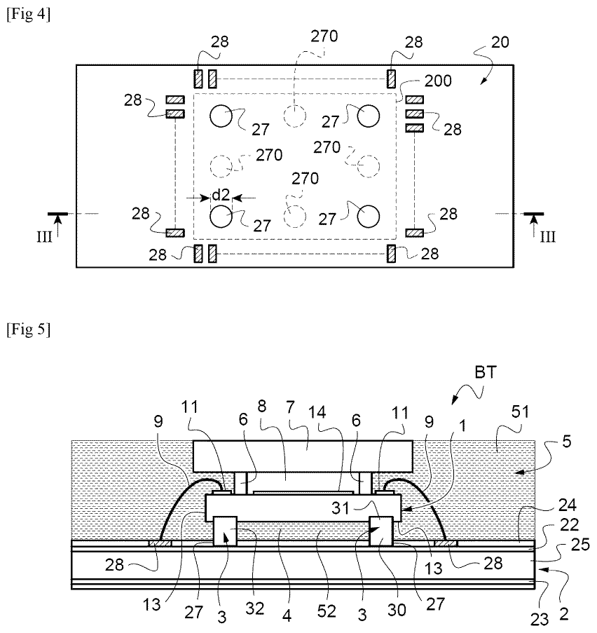

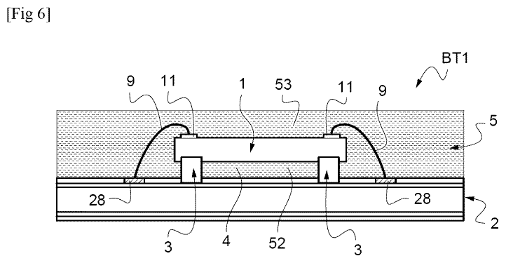

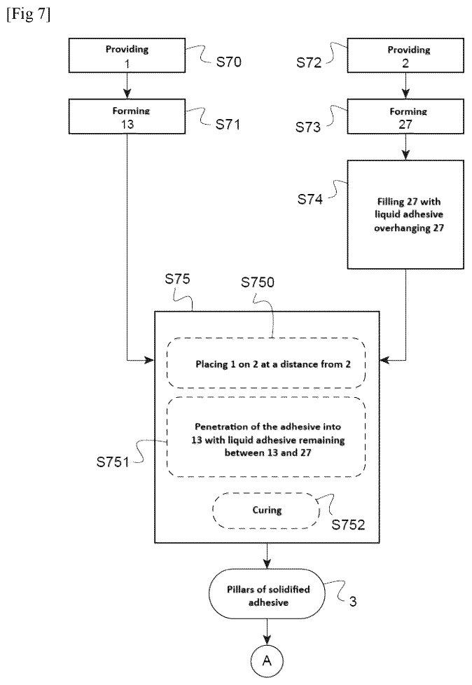

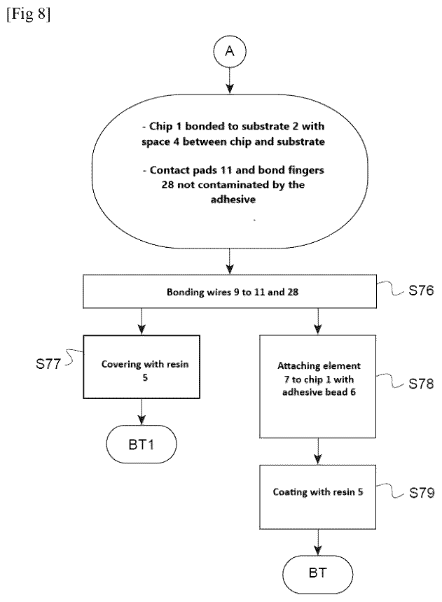

Other advantages and features of the present disclosure will become apparent upon examining the detailed description of non-limiting embodiments and implementations, and from the appended drawings, wherein:

[FIG. 1]; [FIG. 2]; [FIG. 3]; [FIG. 4]; [FIG. 5]; [FIG. 6]; [FIG. 7]; and [FIG. 8] schematically show implementations and embodiments of the present disclosure.

### DETAILED DESCRIPTION

In FIG. 1 and FIG. 2, the reference numeral 1 is used for an electronic chip.

FIG. 1 is a sectional view along the line I-I shown in FIG. 2.

The electronic chip 1 includes a front face 10 having contact pads 11 and a rear face 12.

The chip also includes here an optical device 14 for emitting and/or receiving light signals, mounted on the front face 10 of the chip.

The rear face 12 has a plurality of first blind holes 13 spread around the periphery of the rear face and opening onto this rear face.

In this embodiment, four first blind holes 13 are provided.

A chip is generally rectangular (possibly with equal sides thus forming a square).

In this case, the four first blind holes 13 are preferably, as shown in FIG. 2, arranged in the vicinity of the four corners of the rear face 12 of the electronic chip.

As shown in FIG. 2, the rear face of the chip can include four other first blind holes 130 respectively arranged between the four first blind holes, for example in the middle of the sides of the rear face 12.

In FIGS. 3 and 4, the reference numeral 2 is used for a carrier substrate.

FIG. 3 is a sectional view along the line III-III shown in FIG. 4.

The carrier substrate 2 has a front face (upper face or mounting face) 20 and a rear face (lower face) 21 opposite the front face.

The carrier substrate 2 has on its front face an area 200 which is a placement area above which the chip 1 is intended to be located.

The front face 20 of the carrier substrate has bond fingers 28 outside the placement area 200 and a plurality of second blind holes 27, located at the periphery of the placement area 200, opening onto the front face 20 and intended to be respectively opposite the first blind holes 13 of the chip 1.

When the rear face of the electronic chip has four first blind holes 13, the front face of the carrier substrate has four second blind holes 27.

If the rear face of the chip has four other first blind holes 130, the front face of the carrier substrate has four other second blind holes 270 intended to be respectively located opposite the other four first blind holes.

The carrier substrate 2 is a laminate substrate here.

Such a substrate has alternating metallic 22, 23 (only two are shown for the sake of simplification) and electrically insulating layers 24, 25, 26.

Metal tracks formed in the metallic layers and vias between these tracks provide an interconnection network between the bond fingers 200 on the front face (upper face) of the carrier substrate and solder balls (not shown here) arranged on the rear face (lower face) of the carrier substrate and intended to be soldered to a printed circuit board.

The upper face of the upper electrically insulating layer of the carrier substrate forms the front face of this carrier substrate and the second blind holes 27 are formed here in the upper electrically insulating layer 24 and have a depth p2 corresponding to the thickness of this upper insulating layer 24.

FIG. 5 schematically shows a first embodiment of a package BT including the aforementioned chip 1 and carrier substrate 2.

The rear face 12 of the chip and the front face 20 of the substrate are opposite each other leaving a space 4 between them.

The first blind holes 13 of the chip are respectively opposite the second blind holes 27 of the carrier substrate.

Each pair of a first blind hole 13 and a second blind hole 27 facing each other defines a housing.

The package BT then has a pillar 3 of a first adhesive material, for example a pillar of solidified adhesive, in each housing.

Each pillar 3 has
a lower part 30 housed in the second corresponding blind hole 27,
an upper part 30 housed in the first corresponding blind hole 13, and
an intermediate part 32 between the parts 30 and 31 located in the space between the chip and the carrier substrate.

The package BT also has electrically conductive bond wires 9 between the contact pads 11 of the chip and the bond fingers 28 of the carrier substrate.

The electronic chip 1 is attached to the carrier substrate 2 by means of adhesive material pillars 3.

And this adhesive material is contained in each housing formed by a pair of a first blind hole 13 and a second blind hole 27 facing each other.

There is therefore no contamination of the contact pads 11 and bond fingers 28 by the first adhesive material which enables the bond wires 9 to be properly bonded to these contact pads 11, on the one hand, and to the bond fingers 28, on the other.

The package BT is an optical package here having an optically transparent element 7, for example glass, located opposite and at a distance from the front face of the chip to which the optical device 14 is attached.

The optically transparent element 7 is attached to the front face of the chip by a bead 6 of a second adhesive material, for example an adhesive bead.

This second adhesive material may be identical to or different from the first adhesive material forming the pillars 3.

This bead 6 of the second adhesive material defines with the chip 1 and the optically transparent element 7 a cavity 8.

The package BT also has an encapsulating material 5, for example a molding resin, covering the bond wires 9 and partially the electronic chip 1.

One part 52 of this encapsulating material is located in the space between the rear face of the chip and the front face of the carrier substrate.

Another part 51 of the encapsulating material laterally covers the chip 1, the optically transparent element 4 and the adhesive bead 6.

The cavity 8 is not filled by the encapsulating material 5.

For some packages, the encapsulating material completely covers the electronic chip.

This is the case, for example, for the package BT1 shown schematically in FIG. 6.

This package is a non-optical package.

In FIGS. 5 and 6, similar elements or those having similar functions bear the same reference numerals.

Only the differences between FIG. 5 and FIG. 6 will now be described.

The front face of the chip 1 does not have an optical device and the package BT1 does not have an optically transparent element facing the front face of the chip 1.

The encapsulating material 5 has an upper part 53 here covering the chip 1.

Generally speaking, a person skilled in the art will be able to define the geometric characteristics of the first blind holes and second blind holes as well as the quantity of first adhesive material so as to obtain adhesive pillars filling these blind holes whilst providing a space between the rear face of the chip and the front face of the carrier substrate.

As an example, the second blind holes 27 can have a depth p2 (FIG. 3) of 25 micrometers to within 10%.

The second blind holes 27 can have, as an example, an opening d2 (FIG. 2) of 200 micrometers to within 10%.

The first blind holes 13 (formed on the rear face of the chip) may have a depth p1 (FIG. 1) less than that of the second blind holes, for example a depth p1 of 10 micrometers to within 10%.

Each pillar of the first adhesive material 3 may overhang the front face of the carrier substrate by 20 micrometers to within 10%, which represents the height of the intermediate part 32 of this pillar.

The space between the rear face of the electronic chip and the front face of the substrate therefore has this value of 20 micrometers to within 10%.

Reference is now made more specifically to FIGS. 7 and 8 to describe an embodiment of a method for manufacturing a package according to the present disclosure.

This method comprises providing S70 an electronic chip 1 including a front face having contact pads and a rear face.

On the rear face a plurality of first blind holes 13 are formed (step S71) spread around the periphery of this rear face and opening onto this rear face.

The method also comprises providing S72 a carrier substrate 2 having a front face having a placement area 200 intended to be opposite the rear face of the chip and the bond fingers 28 outside of this placement area 200.

The method then comprises forming S73 at the periphery of the area 200 a plurality of second blind holes 27 opening onto the front face.

The method subsequently comprises filling S74 the second blind holes 27 with a first adhesive material in the liquid state in an amount so as to obtain a surplus of first material overhanging the second blind holes 27.

This first adhesive material may be, for example, the adhesive marketed under the reference ABLESTIK QMI536 by the company Loctite and the second blind holes may be filled conventionally using a syringe.

The surplus of adhesive remains localized in the volume located above each second blind hole 27 due to the edge effect and the surface tension of the adhesive in the liquid state.

The subsequent step S75 involves attaching the chip to the carrier substrate by means of pillars of adhesive 3.

More specifically, just after the filling of the second blind holes 27, the rear face of the chip is placed S750 opposite and at a distance from the placement area 200 of the carrier substrate so as to align the first blind holes 13 and the second blind holes 27 respectively and allow penetration S751 of the surplus of adhesive into the first blind holes 13.

The method then comprises solidifying S752 the first material, typically by curing at an appropriate temperature, for example 150° C. for a period of 90 minutes, so as to obtain the pillars 3 of solidified adhesive extending into each pair of a first blind hole 13 and a second blind hole 27 and into the space between this first and this second blind hole.

At this stage, the electronic chip 1 is bonded to the carrier substrate 2 with a space 4 between the chip and the carrier substrate.

The contact pads 11 and the bond fingers 28 are not contaminated by the adhesive.

The next step is bonding S76 bond wires 9 between the contact pads 11 and the bond fingers 28.

From there, there are two possible variants.

In a first variant, the bond wires and the electronic chip are completely covered S77 with an encapsulating material, for example a conventional molding resin, which is also inserted into the space 4 between the rear face of the chip and the front face of the carrier substrate, so as to obtain a package BT1 like the one shown in FIG. 6.

In a second variant, prior to the covering, the optically transparent element 7 is attached (step S78) opposite and at a distance from the front face of the chip by a bead 6 of a second adhesive material defining with the chip and the optically transparent element the cavity 8 which is not filled by the encapsulating material, for example the molding resin, during covering S79.

In this example, the second adhesive material may be the adhesive used to form the pillars 3.

1. A package comprising:
an electronic chip including a front face having contact pads and a rear face having a plurality of first blind holes spread around a periphery of the rear face and opening onto the rear face;
a carrier substrate having a front face opposite and at a distance from the rear face of the electronic chip and having a plurality of bond fingers and a plurality of second blind holes opening onto the front face respectively opposite the plurality of first blind holes of the electronic chip, each pair of a first blind hole and a second blind hole facing each other defining a housing;
a pillar of a first adhesive material in each housing;
bond wires between the contact pads and the plurality of bond fingers; and
an encapsulating material covering the bond wires and at least partially the electronic chip, part of the encapsulating material being located in a space between the rear face of the electronic chip and the front face of the carrier substrate.

2. The package according to claim 1, wherein the rear face of the electronic chip has at least four first blind holes of the plurality of first blind holes and the front face of the carrier substrate has at least four second blind holes of the plurality of second blind holes.

3. The package according to claim 2, wherein the electronic chip is rectangular with four corners and the at least four first blind holes are arranged in a vicinity of the four corners of the rear face of the electronic chip.

4. The package according to claim 2, wherein the rear face of the electronic chip has four other first blind holes of the plurality of first blind holes that are respectively arranged between the at least four first blind holes, and wherein the front face of the carrier substrate has four other second blind holes of the plurality of second blind holes that are respectively located opposite the four other first blind holes.

5. The package according claim 1, wherein the encapsulating material completely covers the electronic chip.

6. The package according to claim 1, wherein the package is an optical package having an optically transparent element located opposite and at a distance from the front face of the electronic chip and attached to the front face by a bead of a second adhesive material defining with the electronic chip and the optically transparent element a cavity which is not filled by the encapsulating material.

7. The package according to claim 1, wherein the plurality of second blind holes are 25 micrometers deep to within 10%.

8. The package according to claim 1, wherein the carrier substrate is a laminate substrate having alternating metallic and electrically insulating layers, an upper face of an upper electrically insulating layer forming the front face of the carrier substrate and the plurality of second blind holes are formed in the upper electrically insulating layer and have a depth corresponding to a thickness of the upper electrically insulating layer.

9. The package according to claim 1, wherein the plurality of second blind holes each have an opening of 200 micrometers to within 10%.

10. The package according to claim 1, wherein the plurality of first blind holes are 10 micrometers deep to within 10%.

11. The package according to claim 1, wherein each pillar of the first adhesive material overhangs the front face of the carrier substrate by 20 micrometers to within 10%.

12. A method for manufacturing a package, comprising:
providing an electronic chip including a front face having contact pads and a rear face;
forming on the rear face a plurality of first blind holes spread around a periphery of the rear face and opening onto the rear face;
providing a carrier substrate having a front face having an area intended to be opposite the rear face of the electronic chip and a plurality of bond fingers outside of the area;
forming at the periphery of the area a plurality of second blind holes opening onto the front face;
filling the plurality of second blind holes with a first adhesive material in a liquid state in an amount so as to obtain a surplus of a first material overhanging the plurality of second blind holes;
placing the rear face of the electronic chip opposite and at a distance from the area so as to align the plurality of first blind holes and the plurality of second blind holes respectively and allow penetration of the surplus of the first material into the plurality of first blind holes, and solidifying the first material so as to obtain pillars of the first material extending into each pair of a first blind hole and a second blind hole and into a space between each pair;
bonding bond wires between the contact pads and the plurality of bond fingers; and
covering the bond wires and at least part of the electronic chip with an encapsulating material which is also inserted into a space between the rear face of the electronic chip and the front face of the carrier substrate.

13. The method according to claim 12, wherein at least four first blind holes of the plurality of first blind holes are formed and at least four second blind holes of the plurality of second blind holes are formed.

14. The method according to claim 13, wherein the electronic chip is rectangular with four corners and the at least four first blind holes are formed in a vicinity of the four corners of the rear face of the electronic chip.

15. The method according to claim 14, wherein the rear face of the electronic chip has four other first blind holes of the plurality of first blind holes respectively arranged between the at least four first blind holes, and wherein the front face of the carrier substrate has four other second blind holes respectively located opposite the four other first blind holes when the electronic chip is placed.

16. The method according to claim 12, wherein the electronic chip is completely covered with the encapsulating material.

17. The method according to claim 12, wherein prior to the covering, an optically transparent element is attached opposite and at a distance from the front face of the electronic chip by a bead of a second adhesive material defining with the electronic chip and the optically transparent element a cavity which is not filled by the encapsulating material during covering.
